(19) United States
(12) Patent Application Publication
(10) Pub. No.: US 2022/0301887 A1
(43) Pub. Date: Sep. 22, 2022

(54) RUTHENIUM ETCHING PROCESS

(71) Applicant: Applied Materials, Inc., Santa Clara, CA (US)

(72) Inventors: Nasrin Kazem, Santa Clara, CA (US); Jeffrey W. Anthis, San Jose, CA (US)

(73) Assignee: Applied Materials, Inc., Santa Clara, CA (US)

(21) Appl. No.: 17/202,675

(22) Filed: Mar. 16, 2021

(51) Int. Cl. H01L 21/3213; H01L 21/285

(52) U.S. Cl. CPC H01L 21/32136; H01L 21/28568; H01L 28/60

(57) ABSTRACT

Embodiments of this disclosure provide methods for etching ruthenium. A halide-containing-gas is flowed into a substrate processing chamber, and then an oxygen-containing gas is flowed into the substrate processing chamber. The methods may include atomic layer etching (ALE). The methods may be conducted at higher processing chambers, permitting deposition and etching of ruthenium to be conducted in the same processing chamber.

### TECHNICAL FIELD

Embodiments of the disclosure generally relate to methods for etching of ruthenium. In particular, some embodiments of the disclosure are directed to methods of etching ruthenium in the presence of a halogen.

### BACKGROUND

Ruthenium is used in various microelectronics applications due to its high work function (>4.7 eV), low bulk resistivity (7 μΩUcm), high chemical and thermal stability and the fact that ruthenium oxide is conductive. As one example, a thin film of ruthenium may be utilized as a replacement for a TiN capacitor electrode in dynamic random memory (DRAM) applications. The capacitor cells used in DRAMs require high dielectric constant materials such as tantalum pentoxide or barium strontium titanate. Manufacture of these high dielectric constant materials utilizes oxidation processes at relatively high temperatures. A common capacitor electrode, polysilicon, is oxidized under these conditions, and this leads to capacitance loss. Ruthenium is a suitable material for such capacitor electrode applications because ruthenium has a higher oxidation resistance or a high electrical conductivity even in the oxidized state. In another ruthenium thin films can be used as a seed layer for Cu electroplating in combination with a TaN barrier due to the fact that ruthenium adheres to copper.

Ruthenium films can be deposited by various processes, including chemical vapor deposition (CVD) and atomic layer deposition (ALD). Many ruthenium deposition processes are conducted at temperatures greater than 100° C. and greater than 200° C. As part of manufacturing processes, etching is utilized to remove a portion of deposited layers or film. There is a need for ruthenium etching processes that can be conducted at temperatures greater than 100° C. and greater than 200° C.

### SUMMARY

One or more embodiments of the disclosure are directed to an etch method comprising exposing a ruthenium layer on a substrate in a substrate processing chamber to halogen-containing gas for a first period of time; and after exposing the ruthenium layer to the halogen-containing gas, exposing the ruthenium layer to an oxygen-containing gas for a second period of time to etch the ruthenium layer. In some embodiments, a plasma is formed in the substrate processing chamber during exposing the ruthenium layer to an oxygen-containing gas, and the ruthenium layer is exposed to an oxygen plasma.

Additional embodiments of the disclosure are directed to ruthenium deposition and etching process comprising depositing a ruthenium layer on a substrate in a substrate processing chamber; exposing the ruthenium layer in the substrate processing chamber to fluorine-containing gas for a first period of time; and after exposing the ruthenium layer to the fluorine-containing gas, exposing the ruthenium layer to an oxygen-containing gas for a second period of time to anisotropically etch the ruthenium layer at an etch rate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a flowchart of an exemplary method according to one or more embodiment of the disclosure;

FIG. 2 is a flowchart of an exemplary method according to one or more embodiment of the disclosure; and

FIG. 3 is a cross sectional view of an exemplary substrate during processing according to one or more embodiment of the disclosure; and

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on or etching from a substrate can mean both a bare substrate and a substrate with one or more films or features deposited or formed thereon

A “substrate,” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been removed from a substrate surface, the exposed surface of the newly exposed film, layer, or substrate becomes the substrate surface.

As used in this specification and the appended claims, the terms “precursor”, “reactant”, “reactive gas” and the like are used interchangeably to refer to any gaseous species that can react with the substrate surface.

“Atomic layer etching” (ALE) or “cyclical etching” is a variant of atomic layer deposition wherein a surface layer is removed from a substrate. As used herein, ALE refers to the sequential exposure of two or more reactive compounds to etch a layer of material on a substrate surface. The substrate, or portion of the substrate, is exposed separately to the two or more reactive compounds which are introduced into a reaction zone of a processing chamber.

In a time-domain ALE process, exposure to each reactive compound is separated by a time delay to allow each compound to adhere and/or react on the substrate surface and then be purged from the substrate processing chamber. These reactive compounds are said to be exposed to the substrate sequentially.

In one aspect of a time-domain ALE process, a first reactive gas (i.e., a first reactant or compound A (for example, a halide-containing gas such as a fluorine-containing gas such as NF₃) is pulsed into the reaction zone followed by a first time delay. Next, a second reactant or compound B (for example, an oxygen-containing gas such as O₂ or O₃) is pulsed into the reaction zone followed by a second delay. During each time delay, a purge gas, such as argon, is introduced into the substrate processing chamber to purge the reaction zone or otherwise remove any residual reactive compound or reaction by-products from the reaction zone. Alternatively, the purge gas may flow continuously throughout the etching process so that only the purge gas flows during the time delay between pulses of reactive compounds. The reactive compounds are alternatively pulsed until a desired film or film thickness is removed from the substrate surface. Introduction of the halide-containing gas accelerates the rate of etching of ruthenium compared to processes that do not introduce a halide-containing gas. In some embodiments, the oxygen-containing gas comprises or consists of O₃, and a plasma is not formed in the substrate processing chamber during the etching process. In other embodiments, the oxygen-containing gas comprises or consists of O₂, and a plasma is formed as part of the etching process. In specific embodiments, the plasma comprises a capacitively coupled plasma, as opposed to reactive ion etching or inductively coupled plasma etching. In some embodiments, an advantage of the processes described herein is that the etching process has a wide temperature window (e.g., 100° C. to 400° C.), which allows for ruthenium deposition and etching to be conducted in the same chamber without removing the substrate from the substrate processing chamber. Thus, in some embodiments, the need for a substrate etching chamber is eliminated, as embodiments utilize an ALE-type approach to deposition and etching of ruthenium layers in the same process chamber.

The ALE process of pulsing compound A, purge gas, compound B and purge gas is referred to as a cycle. A cycle can start with either compound A or compound B and continue the respective order of the cycle until a predetermined thickness is removed.

In a spatial ALE process, different portions of the substrate surface, or material on the substrate surface, are exposed simultaneously to the two or more reactive compounds so that any given point on the substrate is substantially not exposed to more than one reactive compound simultaneously. As used in this regard, the term “substantially” means, as will be understood by those skilled in the art, that there is the possibility that a small portion of the substrate may be exposed to multiple reactive gases simultaneously due to diffusion, and that the simultaneous exposure is unintended.

In an embodiment of a spatial ALE process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Some embodiments of the present disclosure relate to methods for etching or removing ruthenium from a substrate surface. Some methods of this disclosure advantageously utilize NF₃ as the halogen-containing gas in the presence of a plasma.

One or more embodiments of the disclosure are directed to methods for the removal of ruthenium via anisotropic etching. In some embodiments, a substrate comprising ruthenium layer having a ruthenium surface can be treated with a halogen-containing gas, e.g., fluorine, followed by treatment with an oxygen-containing gas and a subsequent purge. This cycle may be repeated to remove a predetermined thickness of metal/metal oxide.

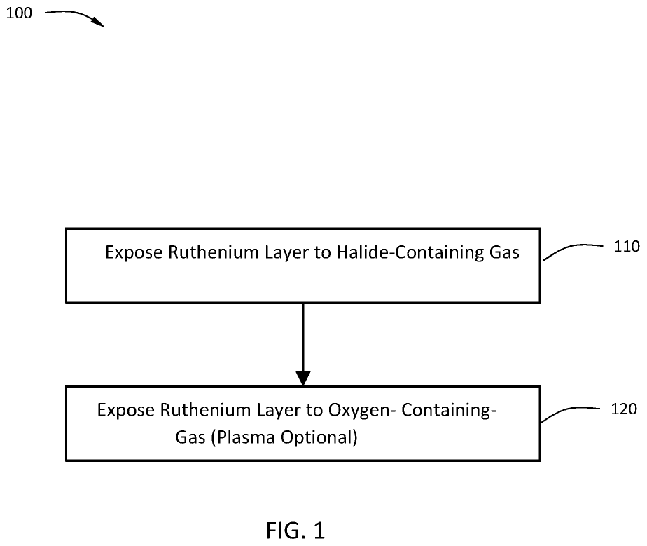

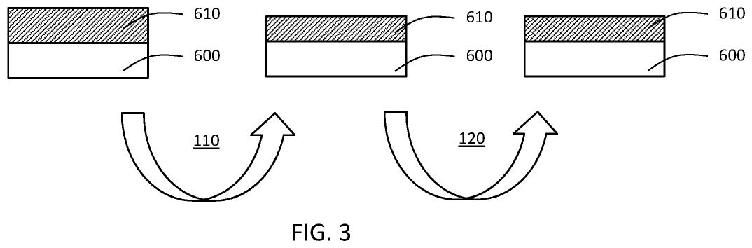

Referring to FIG. 1 and FIG. 3 a method 100 begins at operation 110 with a substrate 600 comprising a ruthenium layer 610 being exposed to a halide-containing gas. The method 100 continues at operation 120 with the ruthenium layer 610 being exposed to an oxygen-containing gas to remove or etch a portion of the ruthenium layer 610. An exemplary reaction scheme for the method 100 shown in FIG. 1 and FIG. 3 comprises exposing a ruthenium layer on a substrate in a substrate processing chamber to halogen-containing gas for a first period of time, forming a plasma in the substrate processing chamber, and after exposing the ruthenium layer to the halogen-containing gas, exposing the ruthenium layer to an oxygen-containing gas for a second period of time to etch the ruthenium further comprising flowing a purge gas after exposing the ruthenium layer to the halogen-containing gas and prior to exposing the ruthenium layer to the oxygen-containing gas.

An exemplary reaction scheme for the method 100 shown in FIG. 1 and FIG. 3 comprises exposing a ruthenium layer on a substrate in a substrate processing chamber to halogen-containing gas for a first period of time, forming a plasma in the substrate processing chamber, and after exposing the ruthenium layer to the halogen-containing gas, exposing the ruthenium layer to an oxygen-containing gas for a second period of time to etch the ruthenium further comprising flowing a purge gas after exposing the ruthenium layer to the halogen-containing gas and prior to exposing the ruthenium layer to the oxygen-containing gas. Exposing the ruthenium layer to a halide-containing gas may be referred to pretreating or pretreatment of the ruthenium layer, which in one or more embodiments results in accelerating the etch rate or removal rate of the ruthenium layer.

In some embodiments, the first period of time is in a range of from one second to 10 minutes, for example, from 5 seconds to 10 minutes, from 10 seconds to 10 minutes, from 30 seconds to 10 minutes, from one minute to 10 minutes, 5 minutes to 10 minutes, from one second to five minutes, from one second to 4 minutes, from one second to three minutes, from one second to 2 minutes or from one second to one minute.

In some embodiments, the halogen-containing gas is flowed into substrate processing chamber at a flow rate in a range of from 10 sccm (standard cubic centimeters per minute) to 5 slm (standard liters per minute).

In some embodiments, the purge gas is flowed for a third period of time in a range of from 10 seconds to 60 seconds, or from 10 to 30 seconds or from 10 to 20 seconds, or from one to 10 seconds or from one to 5 seconds. In some embodiments, the second period of time is in a range of from one second to 10 minutes, for example, from 5 seconds to 10 minutes, from 10 seconds to 10 minutes, from 30 seconds to 10 minutes, from one minute to 10 minutes, 5 minutes to 10 minutes, from one second to five minutes, from one second to 4 minutes, from one second to three minutes, from one second to 2 minutes or from one second to one minute.

In one or more embodiments, the purge gas is selected from the group consisting of argon and nitrogen. In some embodiments, the oxygen-containing gas is selected from the group consisting of O₂, ozone (O₃) and mixtures thereof.

In some embodiments, the halide-containing gas is selected from the group consisting of NF₃, HF, HCl, F₂, Cl₂, I₂, HI, HBr, BrF₃, BrF₅, BCl₃, organofluorides having the general formula CₓH_{y}F_{z}, where x is 1-16, y is 0-33 and z is 1-34, organooxyfluorides having the general formula CₓH_{y}O_{w}F_{z}, where x is 1-16, y is 0-33, w is 1-8 and z is 1-34, metal fluorides, combinations thereof. In some embodiments, etching the ruthenium layer is performed when the ruthenium layer is at a temperature in a range of from 50° C. to 400° C., for example ranges of 50-300° C., 50-200° C., 50-100° C., 100-400° C., 100-300° C., 100-200° C., 150-400° C., 200-400° C. and 200-300° C.

In some embodiments, the substrate processing chamber is at a temperature in a range of from one millitor to 50 Torr, for example one millitor to 10 Torr, one millitor to one Torr, one Torr to 50 Torr, 1 Torr to 10 Torr and one Torr to three Torr.

In some embodiments, the plasma is formed by a capacitively coupled plasma. The plasma source can be any suitable source, including microwave, DC, pulsed DC, and RF plasma sources. A suitable range of RF power for a RF plasma source RF Power 100-400 W, which depend on the particular chamber and the desired etch rate.

According to one or more embodiments, the processes are cyclic processes, providing a more uniform etch across surface. Ruthenium layers can be etched to provide features using an ALE process. The pretreatment described herein enhances the anisotropic etch of ruthenium. The pretreatment in some embodiments cleans up the ruthenium layer. In some embodiment, an oxyhalide of ruthenium (e.g., oxyfluoride) is formed during etching instead of a tetraoxide of ruthenium.

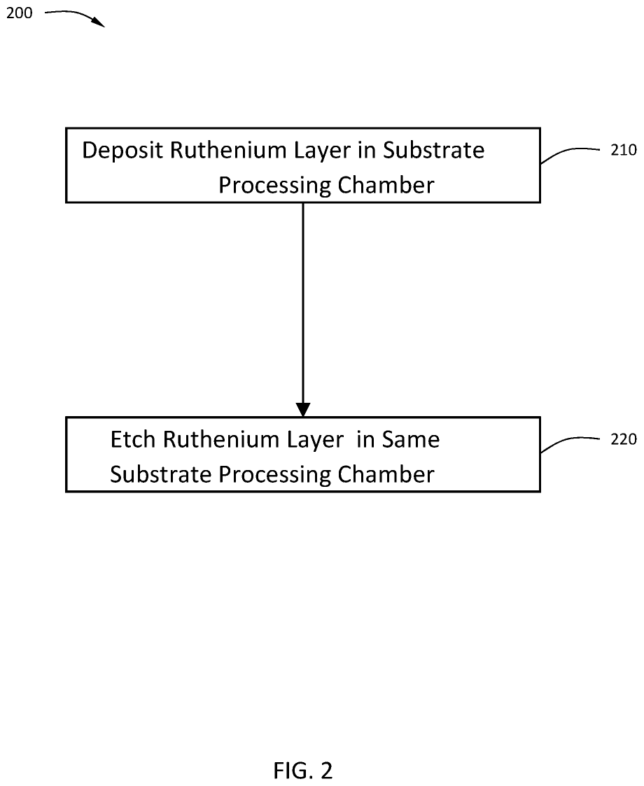

Referring to FIG. 2, a second process scheme is shown, which comprises ruthenium deposition and etching process 200, including depositing a ruthenium layer on a substrate in a substrate processing chamber at operation 210. At operation 220, the ruthenium layer is etched int the same substrate processing chamber in which the deposition occurred. This can occur by exposing the ruthenium layer in the substrate processing chamber to a halide-containing gas, such as fluorine-containing gas for a first period of time, and after exposing the ruthenium layer to the halide-containing gas, exposing the ruthenium layer to an oxygen-containing gas for a second period of time to anisotropically etch the ruthenium layer at an etch rate.

In some embodiments, the oxygen-containing gas comprises 03 and a plasma is not formed in the substrate processing chamber. In some embodiments, etching comprises forming a plasma in the substrate processing chamber. In some embodiments, the fluorine-containing gas comprises NF₃, and the fluorine-containing gas accelerates the etch rate of the ruthenium.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

According to some embodiments, the methods advantageously enhance the anisotropic etch of ruthenium. In some embodiments, pre-treatment of the ruthenium film by halogenation of Ru can accelerate the rate of Ru both in the presence and absence of plasma. In a conformal Ru gap fill, the Ru on the blanket surface can be mainly halogenated using under-dosed NF₃ doses (mainly the top surface exposed to the halogen-containing gas, while the Ru inside the gap is exposed to a lesser degree). At lower dosing rates, there will be a gradient in the NF₃ concentration along the gap structure from the top of the gap to the bottom. In this way, the process enhances the inherent anisotropy associated with the oxygen-containing gas etching to provide V-shaped Ru filled gaps.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. An etch process comprising:
exposing a ruthenium layer on a substrate in a substrate processing chamber to halogen-containing gas for a first period of time; and
after exposing the ruthenium layer to the halogen-containing gas, exposing the ruthenium layer to an oxygen-containing gas and a plasma for a second period of time to etch the ruthenium layer.

2. The etch process of claim 1, further comprising flowing a purge gas after exposing the ruthenium layer to the halogen-containing gas and prior to exposing the ruthenium layer to the oxygen-containing gas.

3. The etch process of claim 2, wherein the first period of time is in a range of from one second to 10 minutes.

4. The etch process of claim 3, wherein the halogen-containing gas is flowed into the substrate processing chamber at a flow rate in a range of from 10 sccm to 5 slm.

5. The etch process of claim 4, wherein the purge gas is flowed for a third period of time in a range of from 10 seconds to 60 seconds.

6. The etch process of claim 5, wherein the second period of time is in a range of from one second to 10 minutes.

7. The etch process of claim 6, wherein the purge gas is selected from the group consisting of argon and nitrogen.

8. The etch process of claim 7, wherein the oxygen-containing gas is selected from the group consisting of O₂ and ozone.

9. The etch process of claim 8, wherein the halogen-containing gas is selected from the group consisting of NF₃, HF, HCl, F₂, Cl₂, I₂, HI, HBr, BrF₃, BrF₅, BCl₃, organofluorides having the general formula CₓH_{y}F_{z}, where x is 1-16, y is 0-33 and z is 1-34, organooxyfluorides having the general formula CₓH_{y}O_{w}F_{z}, where x is 1-16, y is 0-33, w is 1-8 and z is 1-34, metal fluorides, combinations thereof.

10. The etch process of claim 8, wherein the etching the ruthenium layer is performed when the ruthenium layer is at a temperature in a range of from 50° C. to 400° C.

11. The etch process of claim 8, wherein the etching the ruthenium layer is performed when the ruthenium layer is at a temperature in a range of from 100° C. to 400° C.

12. The etch process of claim 8, wherein the etching the ruthenium layer is performed when the ruthenium layer is at a temperature in a range of from 150° C. to 400° C.

13. The etch process of claim 8, wherein the etching the ruthenium layer is performed when the ruthenium layer is at a temperature in a range of from 200° C. to 400° C.

14. The etch process of claim 10, wherein the substrate processing chamber is at a temperature in a range of from one millitor to 50 Torr.

15. The etch process of claim 1, further comprising forming a radio frequency (RF) plasma in the substrate processing chamber.

16. A ruthenium deposition and etching process comprising:
depositing a ruthenium layer on a substrate in a substrate processing chamber;
exposing the ruthenium layer in the substrate processing chamber to fluorine-containing gas for a first period of time; and
after exposing the ruthenium layer to the fluorine-containing gas, exposing the ruthenium layer to an oxygen-containing gas for a second period of time to anisotropically etch the ruthenium layer at an etch rate.

17. The ruthenium deposition and etching process of claim 16, wherein the oxygen-containing gas comprises 03 and a plasma is not formed in the substrate processing chamber.

18. The ruthenium deposition and etching process of claim 16, further comprising forming a plasma in the substrate processing chamber.

19. The ruthenium deposition and etching process of claim 18, wherein forming the plasma comprises forming a capacitively coupled oxygen plasma.

20. The etch process of claim 16, wherein the fluorine-containing gas comprises NF₃, and the fluorine-containing gas accelerates the etch rate of the ruthenium.
